(19) United States
(12) Patent Application Publication
(10) Pub. No.: US 2008/0054880 A1
(43) Pub. Date: Mar. 6, 2008

(54) MEASUREMENT DEVICE, METHOD, PROGRAM, AND RECORDING MEDIUM

(75) Inventors: Kouji MIYAUCHI, Gunma (JP); Yoshihide MARUYAMA, Saitama (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 10/597,451

(22) PCT Filed: Jan. 18, 2005
(86) PCT No.: PCT/JP05/00810

§ 371 Date: Oct. 24, 2006

(30) Foreign Application Priority Data
Jan. 29, 2004 (JP) 2004/021874

(51) Int. Cl. G01R 23/165

(52) U.S. Cl. 324/76.29

(57) ABSTRACT

The level of an output signal output from a device under test is easily adjusted in order to restrain an adverse effect on a result of measuring characteristics of the device under test. A measuring device includes a characteristic measuring unit for measuring characteristics of a device under test based on the output signal output from the device under test, an attenuator for receiving the output signal and adjusting the level of the output signal before supplying it to the characteristic measuring unit, and a level setting unit for setting the degree of the level adjustment of the output signal by the attenuator so as to minimize a measurement error which is caused by the characteristic measurement unit, and changes according to the level of the output signal supplied to the characteristic measuring unit.

### TECHNICAL FIELD

The present invention relates to a technology used to measure characteristics (such as ACLR: Adjacent Channel Leakage Power Ratio) of an output signal output from a device under test (DUT).

### BACKGROUND ART

There has conventionally been practiced a measurement of the ACLR (Adjacent Channel Leakage Power Ratio) of an amplifier which is a DUT (Device Under test) (Refer to a patent document 1 (Japanese Laid-Open Patent Publication (Kokai) No. 2002-319908 (ABSTRACT))).

A signal source supplies an amplifier which is a DUT with a modulated signal. The amplifier amplifies the supplied modulated signal, and outputs the amplified modulated signal. Then, the output signal output from the amplifier is measured by a spectrum analyzer to measure the ACLR of the amplifier.

However, according to the above conventional technology, an error is generated by a distortion and a noise of the spectrum analyzer in the measured result of the ACLR of the amplifier. On this occasion, as the level of the output signal of the amplifier supplied to the spectrum analyzer increases, influence of the distortion of the spectrum analyzer exerted on the measured result increases. On the other hand, as the level of the output signal of the amplifier supplied to the spectrum analyzer increases, influence of the noise of the spectrum analyzer exerted on the measured result decreases. Therefore, if the level of the output signal from the amplifier is properly adjusted by an attenuator or the like, it is possible to restrain the distortion and the noise of the spectrum analyzer from exerting the influence on the measured result, resulting in a reduction of the measurement error.

However, it is difficult to know how to adjust the level of the output signal from the amplifier to reduce the measurement error without a wealth of knowledge in the spectrum analyzer. It is thus difficult to reduce the measurement error by adjusting the level of the output signal from the amplifier.

It should be noted that this difficulty is commonly observed when a measured result of a characteristic of a DUT is influenced by the level of an output signal output from the DUT.

A purpose of the present invention is thus to easily adjust the level of an output signal output from a DUT in order to restrain an adverse effect on a measured result of characteristics of the DUT.

### DISCLOSURE OF THE INVENTION

According to an aspect of the present invention, a measuring device includes: a level adjusting unit that receives an output signal output from a device under test, adjusts a level of the output signal, and outputs the resulting output signal; a characteristic measuring unit that receives the output signal output from the level adjusting unit, and measures a characteristic of the device under test; and a level setting unit that sets a degree of an adjustment of the level of the output signal by the level adjusting unit so that a measurement error is minimum upon the measurement.

According to the thus constructed invention, a level adjusting unit receives an output signal output from a device under test, adjusts a level of the output signal, and outputs the resulting output signal. A characteristic measuring unit receives the output signal output from the level adjusting unit, and measures a characteristic of the device under test. A level setting unit sets a degree of an adjustment of the level of the output signal by the level adjusting unit so that a measurement error is minimum upon the measurement.

According to the present invention, it is preferable that the measurement error is caused by the characteristic measuring unit, and changes according to the level of the output signal supplied to the characteristic measuring unit.

According to the present invention, it is preferable that the measuring device further includes a measurement error calculating unit that calculates the measurement error based on a signal purity, a distortion that increases the measurement error as the level of the output signal increases, and a noise that decreases the measurement error as the level of the output signal increases.

According to the present invention, it is preferable that the distortion is determined based on the IP3 of the measuring device.

According to the present invention, it is preferable that the noise is determined based on a noise level determined based on a frequency of the signal measured by the characteristic measuring unit.

According to the present invention, it is preferable that the noise is determined based on a modulation bandwidth of the output signal.

According to the present invention, it is preferable that the signal purity is determined based on a modulation bandwidth of the output signal.

According to the present invention, it is preferable that the level setting unit discretely sets the degree of the adjustment of the level of the output signal such that the level adjusting unit can adjust the level of the output signal such that the measurement error is minimum within a range equal to or lower than the level of the output signal which minimizes the measurement error.

According to the present invention, it is preferable that the characteristic measuring unit includes a digital processing unit which carries out digital processing; and the level setting unit sets the degree of the adjustment of the level of the output signal such that the level adjusting unit can adjust the level of the output signal such that the measurement error is minimum in a range which can be processed by the digital processing unit.

According to another aspect of the present invention, a measuring method includes: a level adjusting step of receiving an output signal output from a device under test, adjusting a level of the output signal, and outputting the resulting output signal; a characteristic measuring step of receiving the output signal output from the level adjusting step, and measuring a characteristic of the device under test; and a level setting step of setting a degree of an adjustment of the level of the output signal by the level adjusting step so that a measurement error is minimum upon the measurement.

Another aspect of the present invention is a program of instructions for execution by the computer to perform a process of a measuring device having: a level adjusting unit that receives an output signal output from a device under test, adjusts a level of the output signal, and outputs the resulting output signal; and a characteristic measuring unit that receives the output signal output from the level adjusting unit, and measures a characteristic of the device under test; the process including: a level setting step of setting a degree of an adjustment of the level of the output signal by the level adjusting step so that a measurement error is minimum upon the measurement.

Another aspect of the present invention is a computer-readable medium having a program of instructions for execution by the computer to perform a process of a measuring device having: a level adjusting unit that receives an output signal output from a device under test, adjusts a level of the output signal, and outputs the resulting output signal; and a characteristic measuring unit that receives the output signal output from the level adjusting unit, and measures a characteristic of the device under test; the process including: a level setting step of setting a degree of an adjustment of the level of the output signal by the level adjusting step so that a measurement error is minimum upon the measurement.

### BRIEF DESCRIPTION OF THE DRAWINGS

FIG. 1 is a block diagram showing a configuration of a measurement system in which a spectrum analyzer (measuring device) 1 according a first embodiment of the present invention is utilized;

FIG. 2 is a block diagram showing a configuration of the spectrum analyzer (measuring device) 1 according to the first embodiment;

FIG. 3 is a chart showing measurement error components of the ACLR caused by a characteristic measuring unit 8 (especially RF signal processing unit 10);

FIG. 4 is a block diagram showing a configuration of a level setting unit 30 according to the fast embodiment;

FIG. 5 is a block diagram showing a configuration of a distortion calculating unit 322;

FIG. 6 is a block diagram showing a configuration of a noise calculating unit 324;

FIG. 7 is a block diagram showing a configuration of a signal purity calculating unit 326;

FIG. 8 is a flowchart showing an operation of the first embodiment;

FIG. 9 is a flowchart showing an operation to set the attenuation of a attenuator 6;

FIG. 10 is a block diagram showing a configuration of the spectrum analyzer (measuring device) 1 according to a second embodiment;

FIG. 11 is a block diagram showing a configuration of the level setting unit 30 according to the second embodiment; and

FIG. 12 shows charts describing an operation of an optimal level determining unit 340 according to the second embodiment.

### BEST MODE FOR CARRYING OUT THE INVENTION

A description will now be given of embodiments of the present invention with reference to drawings.

### FIRST EMBODIMENT

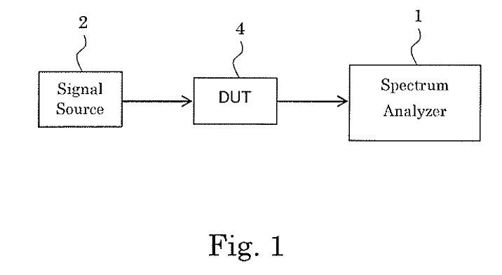

FIG. 1 is a block diagram showing a configuration of a measurement system in which a spectrum analyzer (measuring device) 1 according a first embodiment of the present invention is utilized. The measuring system includes the spectrum analyzer 1, a signal source 2, and a device under test (DUT) 4.

The signal source 2 outputs a modulated signal (one-carrier signal or multi-carrier signal used for the WCDMA, for example).

The device under test (DUT) 4 is an amplifier, for example. The DUT 4 receives the modulated signal from the signal source 2, amplifies the modulated signal, and outputs an output signal.

The spectrum analyzer 1 receives the output signal from the DUT 4, and measures a characteristic (such as the ACLR: Adjacent Channel Leakage Power Ratio) of the DUT 4.

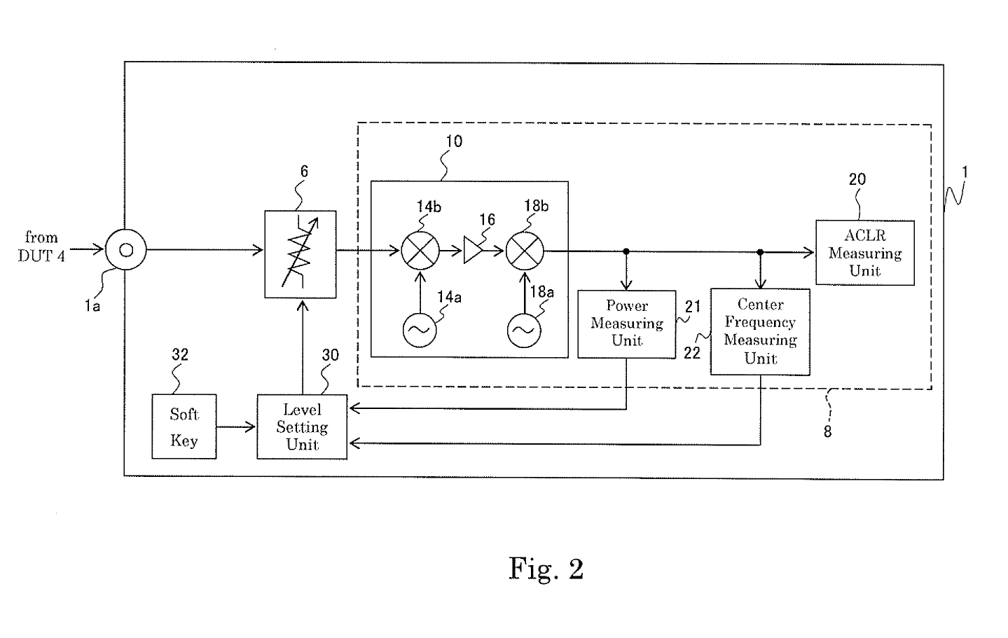

FIG. 2 is a block diagram showing a configuration of the spectrum analyzer (measuring device) 1 according to the first embodiment. The spectrum analyzer 1 includes a terminal la, an attenuator (level adjusting means) 6, a characteristic measuring unit 8, a level setting unit 30, and a soft key 32.

The terminal 1a is a terminal used to receive the output signal from the DUT 4. This output signal is an RF signal.

The attenuator (level adjusting means) 6 receives the output signal from the DUT 4 via the terminal 1a. The attenuator 6 then reduces the level of the output signal, and supplies the characteristic measuring unit 8 with the resulting signal.

The characteristic measuring unit 8 measures the characteristic (such as the ACLR: Adjacent Channel Leakage Power Ratio) of the DUT 4 based on the output signal output from the DUT 4.

The characteristic measuring unit 8 includes an RF signal processing unit 10, an ACLR measuring unit 20, a power measuring unit 21, and a center frequency measuring unit 22.

The RF signal processing unit 10 receives the output signal (RF signal) whose level has been reduced from the attenuator 6, applies down conversion to the output signal, and outputs an IF signal. The RF signal processing unit 10 includes a primary local oscillator 14a, a primary mixer 14b, an amplifier 16, a secondary local oscillator 18a, and a secondary mixer 18b.

The primary local oscillator 14a generates a primary local signal, and supplies the primary mixer 14b with the primary local signal. The primary mixer 14b mixes the output signal (RF signal), whose level has been reduced, from the attenuator 6, and the primary local signal with each other to reduce the frequency. The amplifier 16 amplifies an output from the primary mixer 14b. The secondary local oscillator 18a generates a secondary local signal, and supplies the secondary mixer 18b with the secondary local signal. The secondary mixer 18b mixes an output from the amplifier 16 and the secondary local signal with each other to reduce the frequency. An output from the secondary mixer 18b is the IF signal, and is to be an output from the RF signal processing unit 10.

It should be noted that though the description is given of a case where the two mixers and two local oscillators are used, three or more of them may be used.

The ACLR measuring unit 20 receives the IF signal output from the RF signal processing unit 10, and measures the adjacent channel leakage power ratio (ACLR). The measuring method of the ACLR itself is well known, and a detailed description thereof, therefore, is omitted.

The power measuring unit 21 receives the IF signal output from the RF signal processing unit 10, and measures the power [dBm], A measured result by the power measuring unit 21 is the level of the RF signal supplied to the terminal 1a.

The center frequency measuring unit 22 measures the center frequency of the IF signal output from the RF signal processing unit 10.

The soft key 32 is an input device used by a user of the spectrum analyzer 1 to input the number of carriers of the modulated signal output from the signal source 2. For example, whether the number of carriers is one or more is input. The soft key 32 includes two types of keys;. “ACP” and “Multi Carrier ACP”, for example.

The level setting unit 30 receives the measurement of the power of the IF signal from the power measuring unit 21, the center frequency from the center frequency measuring unit 22, and a signal used to determine the number of the carriers from the soft key 32. Then, the level setting unit 30 sets the degree of the level reduction of the output signal carried out by the attenuator 6 based on the received signal and the like. For example, the level setting unit 30 sets to reduce the level of the output signal by 5 dB or 10 dB by means of the attenuator 6.

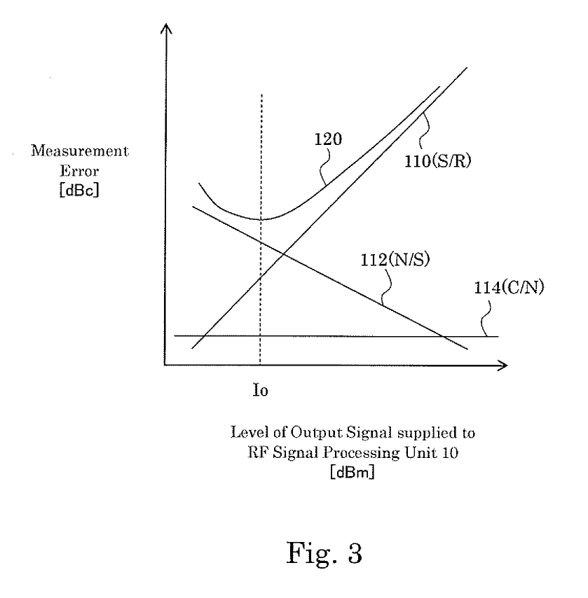

FIG. 3 is a chart showing measurement error components of the ACLR caused by the characteristic measuring unit 8 (especially RF signal processing unit 10). The measurement error components of the ACLR caused by the characteristic measuring unit 8 include three types of measurement error components: distortion (S/R) 110, noise (N/S) 112, and signal purity (C/N) 114. These measurement error components are combined into the measurement error 120. It should be noted that the unit of the distortion (S/R) 110, the noise (N/S) 112, the signal purity (C/N) 114, and the measurement error 120 is dBc. Moreover, the measurement error 120 is added to the ACLR of the DUT 4, and the user of the spectrum analyzer 1 observes the ACLR+measurement error 120 of the DUT 4 as the ACLR of the DUT 4.

As the level of the output signal (RF signal) supplied to the RF signal processing unit 10 increases, the distortion (S/R) 110 increases, and the noise (N/S) 112 decreases. The signal purity (C/N) 114 does not change according to the level of the output signal (RF signal) supplied to the RF signal processing unit 10. As a result, the measurement error 120 takes the minimum value close to an intersection between lines of the distortion (S/R) 110 and the noise (N/S) 112, namely at a level Io of the output signal (RF signal) supplied to the RF signal processing unit 10. The level setting unit 30 sets the degree of the level reduction (attenuation) of the output signal carried out by the attenuator 6 such that the level of the output signal (RF signal supplied to the RF signal processing unit 10 is Io.

For example, it is assumed that the level Io=−20 dBm, and the level of the RF signal supplied to the terminal 1a (measured by the power measuring unit 21) is −5 dBm. In this case, the attenuator 6 is set to reduce the level of the output signal by −5−(−20)=15 dB.

It should be noted that the level reduction quantity of the attenuator 6 may be adjusted only discretely. For example, the level reduction quantity may be adjusted only in 5 dB interval. On this occasion, it is assumed that the level Io=−17 dBm, and the level of the RF signal supplied to the terminal 1a is −10 dBm. In this case, if the attenuator 6 reduces the level by 5 dB, there is obtained −10−5=−15 dBm, and if the attenuator 6 reduces the level by 10 db, there is obtained −10−10=−20 dm. Either case does not attain the level Io. In this case, the attenuation is set to minimize the measurement error 120 within a range of the level of the output signal (RF signal) supplied to the RF signal processing unit 10 equal to or lower than the level Io. Thus, the level is reduced by 10 dB, and the signal at the level of −10−10=−20 dBm n is supplied to the RF signal processing unit 10. If the attenuator 6 reduced the level by 5 dB, the resulting level would be −10−5=−15 dBm>−17 dBm, and the attenuator 6 would not thus reduce the level by 5 dB.

If the level of the signal supplied to the RF signal processing unit 10 is lower, the measurement error will be highly possible reduced in consideration of a noise correction function of the RF signal processing unit 10. The level of the output signal (RF signal) supplied to the RF signal processing unit 10 is thus set to minimize the measurement error 120 in the range equal to or lower than the level Io.

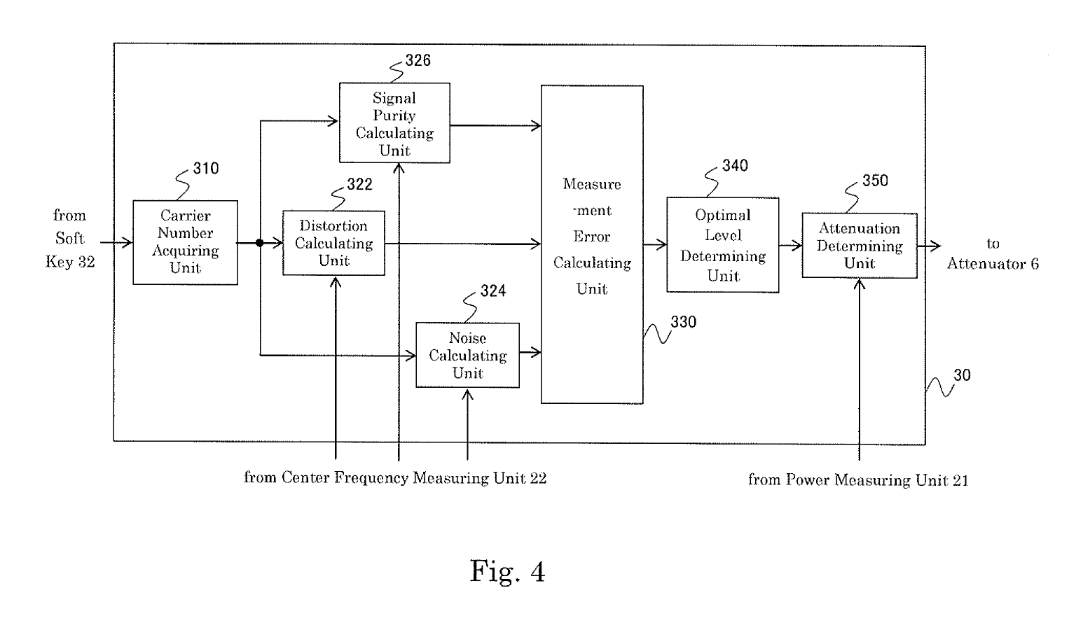

FIG. 4 is a block diagram showing a configuration of a level setting unit 30 according to the first embodiment. The level setting unit 30 includes a carrier number acquiring unit 310, a distortion calculating unit 322, a noise calculating unit 324, a signal purity calculating unit 326, a measurement error calculating unit 330, an optimal level determining unit 340, and an attenuation determining unit 350.

The carrier number setting unit 310 acquires the number of the carriers of the modulated signal output from the signal source 2 based on an information on which key of the soft key 32 has been depressed. If the “ACP” of the soft key 32 is depressed, information indicating one carrier is acquired, and if the “Multi Carrier ACP” thereof is depressed, information indicating multiple carriers (multi-carrier) is acquired.

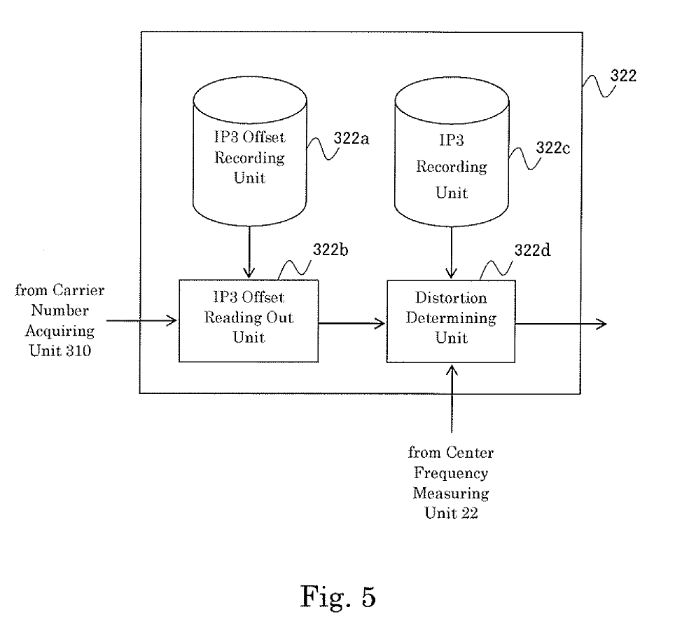

The distortion calculating unit 322 receives the carrier number from the carrier number setting unit 310, and the center frequency from the center frequency measuring unit 22, and then calculates the distortion (S/R) 110. FIG. 5 is a block diagram showing a configuration of the distortion calculating unit 322. The distortion calculating unit 322 includes an IP3 offset recording unit 322a, an IP3 offset reading out unit 322b, an IP3 recording unit 322c, and a distortion determining unit 322d.

The IP3 offset recording unit 322a records IP3 offsets which are associated ,with carrier numbers of the modulated signal. For example, the IP3 offset is 8 dB for a one-carrier signal, and −5 dB for a multi-carrier signal. It is assumed that the signal source 2 outputs a modulated signal according to the WCDMA.

The IP3 offset reading out unit 322b receives the carrier number from the carrier number setting unit 310. The IP3 offset reading out unit 322b then reads out an IP3 offset corresponding to the received carrier number from the IP3 offset recording unit 322a, and outputs the IP3 offset.

The IP3 recording unit 322c records IP3s which are associated with center frequencies of the IF signal output from the RF signal processing unit 10. It should be noted that the definition of the IP3 (intercept point) is well known, and a detailed description thereof, therefore, is omitted. The recorded IP3s may be standard values which are defined by a manufacturer of the spectrum analyzer 1, or may be values obtained by actual measurement by the spectrum analyzer 1. Moreover, the IP3 recording unit 322c may be implemented by an EEPROM.

The distortion determining unit 322d receives the center frequency from the center frequency measuring unit 22, and reads out an IP3 corresponding to the received center frequency from the IP3 recording unit 322c. The distortion determining unit 322d then receives an IP3 offset from the IP3 offset reading out unit 322b. Further, the distortion determining unit 322d determines the distortion S/R as described below.

S/R=−(IP3+IP3 Offset−Input Level)×2

It should be noted that “IP3 Offset” denotes the IP3 offset, and “Input Lever” denotes the level of the output signal (RF signal) supplied to the RF signal processing unit 10. “Input Level” is a variable ranging from −25 to +10 dBm. The distortion (S/R) 110 (refer to FIG. 3) is acquired by plotting the distortion S/R acquired in this way while “Input Level” is assigned to the horizontal axis.

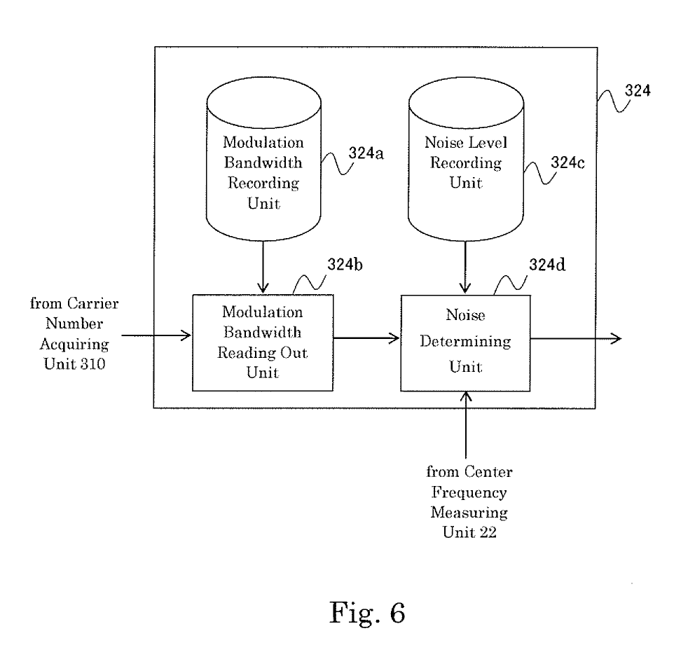

The noise calculating unit 324 receives the carrier number from the carrier number setting unit 310, and the center frequency from the center frequency measuring unit 22, and then calculates the noise (N/S) 112. FIG. 6 is a block diagram showing a configuration of the noise calculating unit 324. The noise calculating unit 324 includes a modulation bandwidth recording unit 324a, a modulation bandwidth reading out unit 324b, a noise level recording unit 324c, and a noise determining unit 324d.

The modulation bandwidth recording unit 324a records modulation bandwidths which are associated with carrier numbers of the modulated signal. For example, the modulation bandwidth is 3.84 MHz for the multi-carrier signal. It is assumed that the signal source 2 outputs a modulated signal according to the WCDMA.

The modulation bandwidth reading out unit 324b receives the carrier number from the carrier number setting unit 310. The modulation bandwidth reading out unit 324b then reads out a modulation bandwidth corresponding to the received carrier number from the modulation bandwidth recording unit 324a, and outputs the read modulation bandwidth.

The noise level recording unit 324c records noise levels which axe associated with center frequencies of the IF signal output from the RF signal processing unit 10. The noise level is a component of the noise N/S determined by the center frequency. The recorded noise levels may be standard values which are defined by a manufacturer of the spectrum analyzer 1, or may be values obtained by actual measurement by the spectrum analyzer 1. Moreover, the noise level recording unit 324c may be implemented by an EEPROM.

The noise determining unit 324d receives the center frequency from the center frequency measuring unit 22, and reads out a noise level corresponding to the received center frequency from the noise level recording unit 324c. The noise determining unit 324d then receives the modulation bandwidth from the modulation bandwidth reading out unit 324b. Further, the noise determining unit 324d determines the noise N/S as described below.

N/S=Noise Level−Input Level+10×log(BW)

It should be noted that “Noise Level” denotes the noise level, “Input Level” denotes the level of the output signal (RF signal) supplied to the RF signal processing unit 10, and “BW” denotes the modulation bandwidth. “Input Level” is a variable ranging from −25 to +10 dBm. The noise (N/S) 112 (refer to FIG. 3) is acquired by plotting the noise N/S acquired in this way while “input Level” is assigned to the horizontal axis.

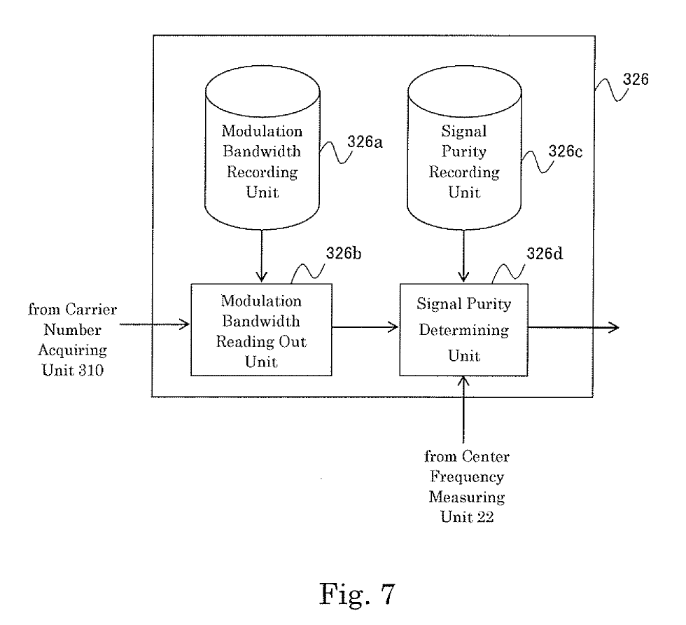

The signal purity calculating unit 326 receives the carrier number from the carrier number setting unit 310, and the center frequency from the center frequency measuring unit 22, and then calculates the signal purity (C/N) 114. FIG. 7 is a block diagram showing a configuration of the signal purity calculating unit 326. The signal purity calculating unit 326 includes a modulation bandwidth recording unit 326a, a modulation bandwidth reading out unit 326b, a signal purity standard value recording unit 326c, and a signal purity determining unit 326d.

The modulation bandwidth recording unit 326a records modulation bandwidths which are associated with carrier numbers of the modulated signal. For example, the modulation bandwidth is 3.84 MHz for the multi-carrier signal It is assumed that the signal source 2 outputs a modulated signal according to the WCDMA.

The modulation bandwidth reading out unit 326b receives the carrier number from the carrier number setting unit 310. The modulation band width reading out unit 326b then reads out a modulation bandwidth corresponding to the received carrier number from the modulation bandwidth recording unit 326a, and outputs the read modulation bandwidth.

The signal purity recording unit 326c records signal purity values which are associated with center frequencies of the IF signal output from the RE signal processing unit 10. The recorded signal purity values may be standard values which are defined by a manufacturer of the spectrum analyzer 1, or may be values obtained by actual measurement by the spectrum analyzer 1. Moreover, the signal purity recording unit 326c may be implemented by an EEPROM.

The signal purity determining unit 326d receives the center frequency from the center frequency measuring unit 22, and reads out an signal purity value corresponding to the received center frequency from the signal purity recording unit 326c. The signal purity determining unit 326d then receives the modulation bandwidth from the modulation bandwidth reading out unit 326b. Further, the signal purity determining unit 326d determines the signal purity C/N as described below.

C/N=CN_{—}CW+10×log(BW)

It should be noted that CN_CW denotes the value of the signal purity read out from the signal purity recording unit 326c. “Input Level” denotes a variable ranging from −25 to +10 dBm. The signal purity (C/N) 114 (refer to FIG. 3) is acquired by plotting the signal purity C/N acquired in this way while “Input Level” is assigned to the horizontal axis.

The measurement error calculating unit 330 calculates the measurement error based on the distortion (S/R) calculated by the distortion calculating unit 322, the noise (N/S) calculated by the noise calculating unit 324, and the signal purity (C/N) calculated by the signal purity calculating unit 326. It should be noted that the measurement error is calculated as described below.

Measurement Error=10×log (10^{{(S/R)/10}}+10^{{(N/S)/10}}+10^{{(C/N)/10}})

The optimal level determining unit 340 determines the level Io (refer to FIG. 3) which minimizes the measurement error 120.

The attenuation determining unit 350 receives the level Io from the optimal level determining unit 340. Moreover, the attenuation determining unit 350 receives the measurement of the power of the IF signal from the power measuring unit 21. The attenuation determining unit 350 then subtracts the level Io from the power of the IF signal to determine the degree of the level reduction (attenuation) carried out by the attenuator 6, and sets the attenuation carried out by the attenuator 6. It should be noted that if the level reduction quantity of the attenuator 6 can be adjusted only discretely, the attenuation of the attenuator 6 is set to minimize the measurement error 120 in the range of the output signal (RF signal) supplied to the RF signal processing unit 10 equal to or lower than the level Io.

A description avid now be given of an operation of the first embodiment.

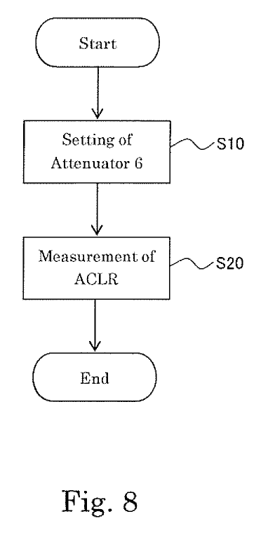

FIG. 8 is a flowchart showing the operation of the first embodiment.

First, the level setting unit 30 sets the attenuation of the attenuator 6 (S10). Then, the modulated signal is output from the signal source 2, and is supplied to the DUT 4. The DUT 4 receives the modulated signal, amplifies the modulated signal, and output the output signal. The spectrum analyzer 1 receives the output signal from the DUT 4, and measures the adjacent channel leakage power ratio (ACLR) of the DUT 4 (S20). On this occasion, since the attenuation of the attenuator 6 is set to minimize the measurement error, it is possible to more accurately measure the adjacent channel leakage power ratio of the DUT 4.

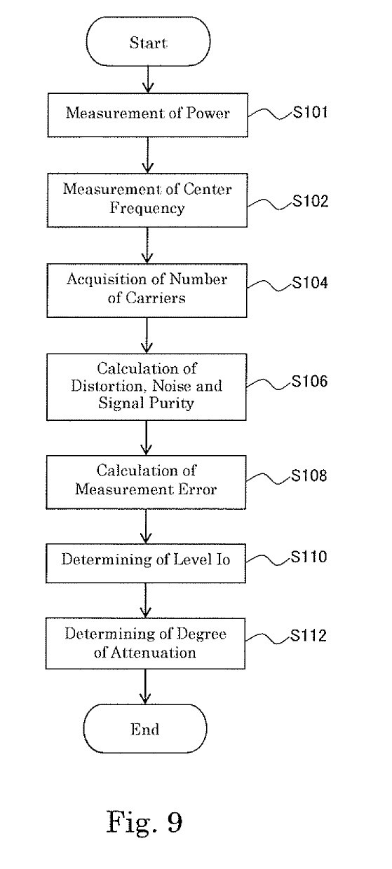

FIG. 9 is a flowchart showing an operation to set the attenuation of the attenuator 6.

First, the modulated signal is output from the signal source 2, and is supplied to the DUT 4. The DUT 4 receives the modulated signal, amplifies the modulated signal, and outputs the output signal. The spectrum analyzer 1 receives the output signal from the DUT 4.

The output signal is supplied to the characteristic measuring unit 8 via the attenuator 6 (the attenuation is set to large (approximately 40 dB, for example)). The output signal is converted in the IF signal by the RF signal processing unit 10, and the converted signal is supplied to the power measuring unit 21. The power measuring unit 21 measures the power [dBm] of the IF signal (S101).

The IF signal is also supplied to the center frequency measuring unit 22. The center frequency measuring unit 22 measures the center frequency of the IF signal (S102).

Moreover, the user of the spectrum analyzer 1 depresses the soft key 32 to input the number of the carriers of the modulated signal output from the signal source 2. As a result, the carrier number acquisition unit 310 of the level setting unit 30 acquires the number of carriers of the modulated signal output from the signal source 2 (S104).

The level setting unit 30 receives the measurement of the power of the IF signal from the power measuring unit 21, and receives the center frequency from the center frequency measuring unit 22. Then, the distortion (S/R) 110, the noise (N/S) 112, and the signal purity (C/N) 114 are calculated (S106).

Moreover, the measurement error calculating unit 330 calculates the measurement error 120 based on the distortion (S/R) 110, the noise (N/S) 112, and the signal purity (C/N) 114 (S108).

Then, the optimal level determining unit 340 determines the level Io (refer to FIG. 3) which minimizes the measurement error 120 (S110).

Finally, the attenuation determining unit 350 determines the degree of the level reduction (attenuation) carried out by the attenuator 6 based on the level Io and the measurement of the power of the IF signal (S112). The determined attenuation is set as the attenuation carried out by the attenuator 6.

According to the first embodiment, the level setting unit 30 sets the degree of the level reduction (attenuation) of the output signal carried out by the attenuator 6 such that the measurement error 120 which is a composition of the measurement error components of the ACLR due to the characteristic measuring unit 8 is minimum. The adjacent channel leakage power ratio of the DUT 4 thus can be more precisely measured.

### SECOND EMBODIMENT

A second embodiment is different from the first embodiment in that the characteristic of the DUT 4 measured by the spectrum analyzer 1 is the EVM (Error Vector Magnitude)

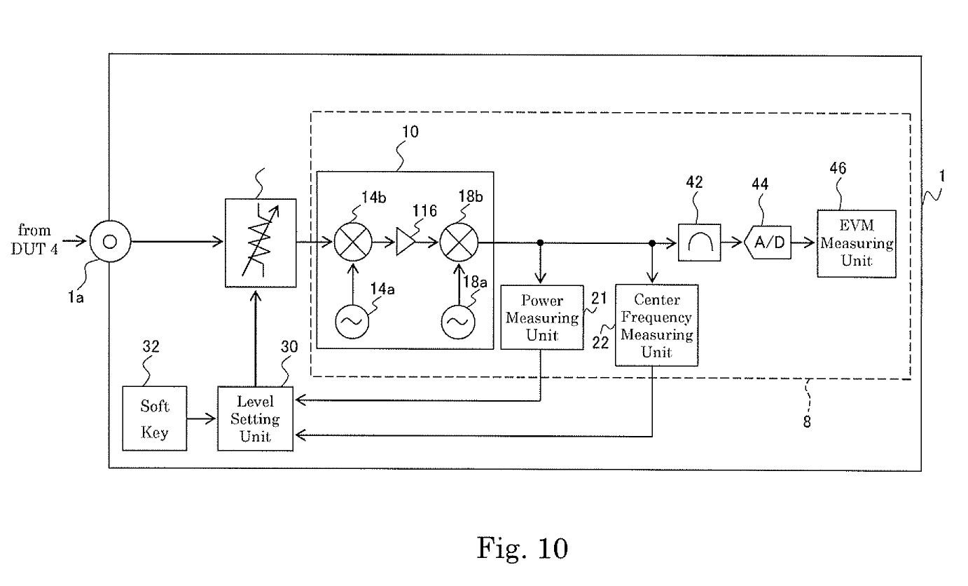

FIG. 10 is a block diagram showing a configuration of the spectrum analyzer (measuring device) 1 according to the second embodiment. The spectrum analyzer 1 includes the terminal 1a, the attenuator (level adjusting means) 6, the characteristic measuring unit 8, the level setting unit 30, and the soft key 32. In the following section, similar components are denoted by the same numerals as of the first embodiment, and swill be explained in no more details.

The terminal 1a, the attenuator (level adjusting means) 6, and the soft key 32 are the same as those of the first embodiment, and a detailed description thereof, therefore, is omitted

The characteristic measuring unit 8 measures the characteristic, the EVM (Error Vector Magnitude), of the DUT 4 based on the output signal output from the DUT 4.

The characteristic measuring unit 8 includes the RF signal processing unit 10, the power measuring unit 21, the center frequency measuring unit 22, a band-pass filter 42, an A/D converter (digital processing means) 44, and an EVM measuring unit 46. The RF signal processing unit 10, the power measuring unit 21, and the center frequency measuring unit 22 are the same as those of the first embodiment, and a detailed description thereof, therefore, is omitted.

The band-pass filter 42 passes a signal within a predetermined band of the IF signal. The AID converter 44 converts an IF signal (which is an analog signal) which has passed the band-pass filter 42 into a digital signal. The EVM measuring unit 46 measures the EVM of the DUT 4 based on the IF signal converted into the digital signal by the A/D converter 44. The measuring method of the EVM itself is well known, and a detailed description thereof, therefore, is omitted.

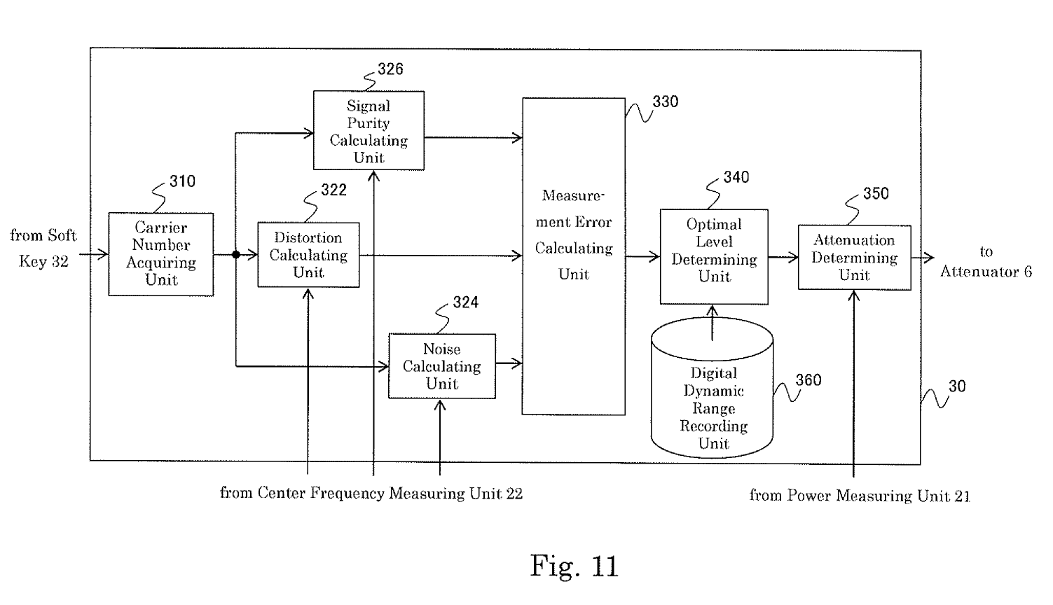

FIG. 11 is a block diagram shoving a configuration of the level setting unit 30 according to the second embodiment. The level setting unit 30 includes the carrier number acquiring unit 310, the distortion calculating unit 322, the noise calculating unit 324, the signal purity calculating unit 326, the measurement error calculating unlit 330, the optimal level determining unit 340, the attenuation determining unit 350, and a digital dynamic range recording unit 360.

The carrier number acquiring unit 310, the distortion calculating unit 322, the noise calculating unit 324, the signal purity calculating unit 326, the measurement error calculating unit 330, and the attenuation determining unit 350 are the same as those of the first embodiment, and a detailed description thereof, therefore, is omitted.

The digital dynamic range recording unit 360 records the dynamic range D of the A/D converter 44, namely the maximum value of the level of the digital signal output from the A/D converter 44.

The optimal level determining unit 340 reads out the dynamic range D from the digital dynamic range recording unit 360. The optimal level determining unit 340 then determines a level which minimizes the measurement error 120 within a range equal to or lower than the dynamic range D.

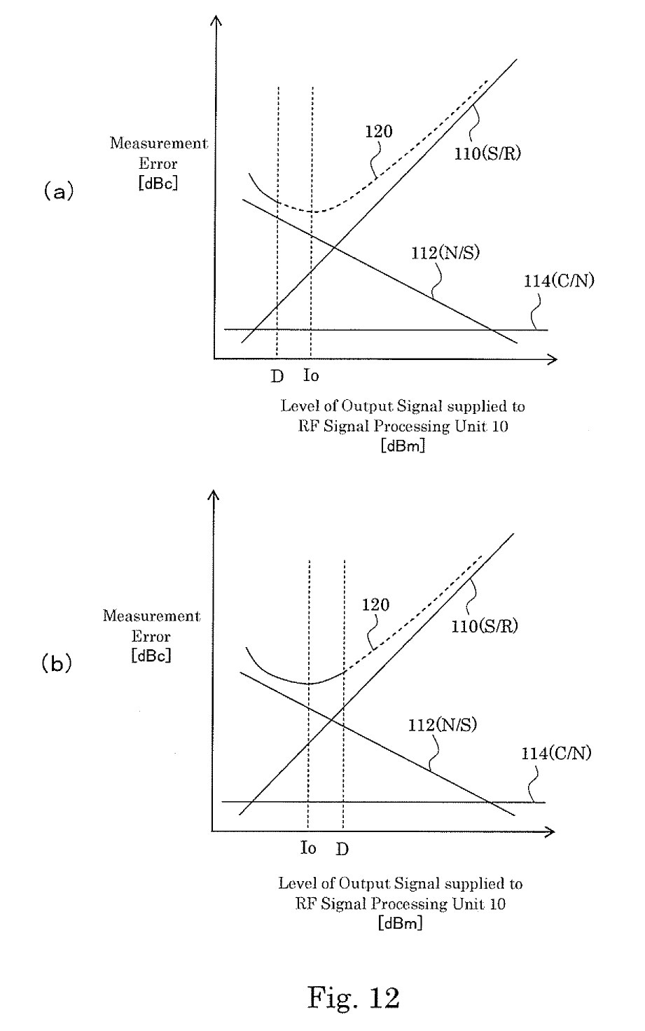

FIG. 12(a) and 12(b) are charts describing an operation of the optimal level determining unit 340 according to the second embodiment. As shown in FIG. 12(a), if dynamic range D<level Io, the dynamic range D is the level which minimizes the measurement error 120. As shown in FIG. 12(b), if dynamic range D>level Io, the level Io is the level which minimizes the measurement error 120.

The attenuation determining unit 350 receives the level determined by the optimal level determining unit 340. Moreover, the attenuation determining unit 350 receives the measurement of the power of the IF signal from the power measuring unit 21. The attenuation determining unit 350 then subtracts the level determined by the optimal level determining unit 340 from the power of the IF signal to determine the degree of the level reduction (attenuation) carried out by the attenuator 6, and sets the attenuation of the attenuator 6. It should be noted that if the level reduction quantity of the attenuator 6 can be adjusted only discretely, the attenuation of the attenuator 6 is set to minimize the measurement error 120 in the range of the output signal (RF signal) supplied to the RF signal processing unit 10 equal to or lower than the level Io.

An operation of the second embodiment is the same as that of the first embodiment.

According to the second embodiment, even if there is required digital processing such as the measurement of the EVM of the DUT 4, the level setting unit 30 sets the degree of the level reduction (attenuation) of the output signal carried out by the attenuator 6 according to the dynamic range of the digital processing. The EVM of the DUT 4 thus can be more precisely measured.

Moreover, the above-described embodiment may be realized in the following manner. A computer is provided with a CPU, a hard disk, and a media (such as a floppy disk (registered trade mark) and a CD-ROM) reader, and the media reader is caused to read a medium recording a program realizing the above-described respective components (such as the level setting unit 30), thereby installing the program on the hard disk. This method may also realize the above-described functions.

1. A measuring device comprising:
a level adjuster that receives an output signal output from a device under test, adjusts a level of the output signal, and outputs the resulting output signal;
a characteristic measurer that receives the output signal output from said level adjuster, and measures a characteristic of the device under test; and
a level setter that sets a degree of an adjustment of the level of the output signal by said level adjuster so that a measurement error is minimum upon the measurement.

2. The measuring device according to claim 1, wherein the measurement error is caused by said characteristic measurer, and changes according to the level of the output signal supplied to said characteristic measurer.

3. The measuring device according to claim 1, comprising a measurement error calculator that calculates the measurement error based on a signal purity, a distortion that increases the measurement error as the level of the output signal increases, and a noise that decreases the measurement error as the level of the output signal increases.

4. The measuring device according to claim 3, wherein the distortion is determined based on the IP3 of the measuring device.

5. The measuring device according to claim 3, wherein the noise is determined based on a noise level determined based on a frequency of the signal measured by said characteristic measurer.

6. The measuring device according to claim 3, wherein the noise is determined based on a modulation bandwidth of the output signal.

7. The measuring device according to claim 3, wherein the signal purity is determined based on a modulation bandwidth of the output signal.

8. The measuring device according to claim 1, wherein said level setter discretely sets the degree of the adjustment of the level of the output signal such that said level adjuster can adjust the level of the output signal such that the measurement error is minimum within a range equal to or lower than the level of the output signal which minimizes the measurement error.

9. The measuring device according to claim 1, wherein:
said characteristic measurer comprises a digital processor which carries out digital processing; and
said level setter sets the degree of the adjustment of the level of the output signal such that said level adjust can adjust the level of the output signal such that the measurement error is minimum in a range which can be processed by the digital processor.

10. A measuring method comprising:
receiving an output signal output from a device under test, adjusting a level of the output signal, and outputting the resulting output signal;
receiving the resulting output signal, and measuring a characteristic of the device under test; and
setting a degree of an adjustment of the level of the resulting output signal so that a measurement error is minimum upon the measurement.

11. A program of instructions for execution by the computer to perform a process of a measuring device having: a level adjuster that receives an output signal output from a device under test, adjusts a level of the output signal, and outputs the resulting output signal; and a characteristic measurer that receives the output signal output from said level adjuster, and measures a characteristic of the device under test; said process comprising:
setting a degree of an adjustment of the level of the output signal by said level adjuster so that a measurement error is minimum upon the measurement.

12. A computer-readable medium having a program of instructions for execution by the computer to perform a process of a measuring device having: a level adjuster that receives an output signal output from a device under test, adjusts a level of the output signal, and outputs the resulting output signal; and a characteristic measurer that receives the output signal output from said level adjuster, and measures a characteristic of the device under test; said process comprising:
setting a degree of an adjustment of the level of the output signal by said level adjuster so that a measurement error is minimum upon the measurement.
